(19) United States
(12) Patent Application Publication
(10) Pub. No.: US 2018/0091127 A1
(43) Pub. Date: Mar. 29, 2018

(54) DELAY CIRCUITS

(71) Applicant: Vanguard International Semiconductor Corporation, Hsinchu (TW)

(72) Inventors: Sheng-Chih CHUANG, Pingtung City (TW); Wei-Chung WU, Kaohsiung City (TW); Szu-Chi CHEN, Jhudong Township (TW)

(73) Assignee: Vanguard International Semiconductor Corporation, Hsinchu (TW)

(21) Appl. No.: 15/274,278

(22) Filed: Sep. 23, 2016

(51) Int. Cl. H03K 5/135

(52) U.S. Cl. CPC H03K 5/135; H03K 2005/00195

(57) ABSTRACT

A delay circuit is provided. The delay circuit includes a voltage-generation circuit and a signal-generation circuit. The voltage-generation circuit receives an input signal and generates a first control voltage and a second control voltage. The signal-generation circuit is controlled by the first control voltage and a second control voltage to generate an output signal. A first delay time by which a falling edge of the output signal is delayed from a falling edge of the output signal is determined by the first control voltage. A second delay time by which a rising edge of the output signal is delayed from a rising edge of the output signal is determined by the second control voltage.

### BACKGROUND OF THE INVENTION

### Field of the Invention

The invention relates to a delay circuit, and more particularly, to a delay circuit for determining delay time according to a rising slope and a falling slope of a delay control signal.

### Description of the Related Art

A delay circuit is a circuit which is capable of delaying an input signal by a specific time to generate an output signal. Thus, after a signal is input to a delay circuit, there is a delay of a specific time between a delayed signal output from the delay circuit and the input signal. In recent years, with the improvement in manufacturing process techniques, the operation speed of system circuits has become higher, and the number of circuits integrated into one chip has increased. Thus, clock synchronization between circuits has become more important. Clock skew is a main factor for determining system performance, especially in a high-speed system. Delay circuits are widely applied for eliminating the clock skew. In current delay circuits, the expected delay time may be achieved by increasing the number of capacitive and resistive elements or the number of inverters. However, the increase in the number of elements in the delay circuit causes an increase in the area of the entire circuit.

### BRIEF SUMMARY OF THE INVENTION

An exemplary embodiment of a delay circuit is provided. The delay circuit comprises a voltage-generation circuit and a signal-generation circuit. The voltage-generation circuit receives an input signal and generates a first control voltage and a second control voltage. The signal-generation circuit is controlled by the first control voltage and a second control voltage to generate an output signal. A first delay time by which a falling edge of the output signal is delayed from a falling edge of the output signal is determined by the first control voltage. A second delay time by which a rising edge of the output signal is delayed from a rising edge of the output signal is determined by the second control voltage.

Another exemplary embodiment of a delay circuit is provided. The delay circuit comprises a first P type-transistor, a first N-type transistor, a second P-type transistor, a second N-type transistor, and an inverter. The first P type-transistor has a gate receiving a first low operation voltage, a source receiving an input signal, and a drain coupled to a first node. The first N-type transistor has a gate receiving a first high operation voltage, a drain receiving the input signal, and a source coupled to a second node. The second P-type transistor has a gate coupled to the first node, a source coupled to a second high operation voltage, and a drain coupled to a third node. The second N-type transistor has a gate coupled to the second node, a drain coupled to the third node, and a source coupled to a second low operation voltage. The inverter is coupled to the third node. The inverter generates an output signal delayed from the input signal. The first P-type transistor and the first N-type transistor are turned on simultaneously.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of a delay circuit;

FIG. 2 shows another exemplary embodiment of a delay circuit;

FIG. 3 is a timing chart showing waveforms of key signals of a delay circuit in accordance with an exemplary embodiment of the invention; and

FIG. 4 shows another exemplary embodiment of a delay circuit.

### DETAILED DESCRIPTION OF THE INVENTION

To better understand the technical aspects of the present invention, the following embodiments of the invention will be described in detail by referring to the drawings.

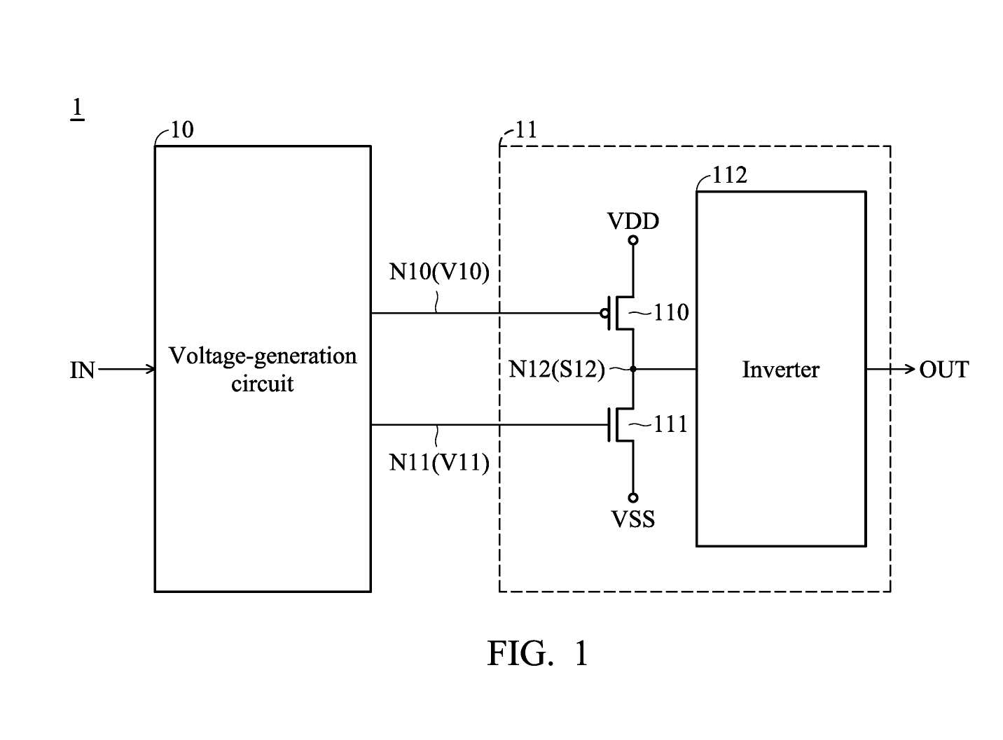

FIG. 1 shows an exemplary embodiment of a delay circuit. Referring to FIG. 1, a delay circuit receives an input signal IN and generates an output signal OUT delayed from the input signal IN. In the embodiment, the input signal IN is a signal which is composed of at least one pulse. In other words, the level of the input signal IN switches between a high level and a low level, and the output signal OUT delayed from the input signal IN also switches between a high level and a low level. The delay circuit comprises a voltage-generation circuit 10 and a signal-generation circuit 11. The signal-generation circuit 11 comprises a P-type metal-oxide-semiconductor (PMOS) transistor 110, an N-type metal-oxide-semiconductor (NMOS) transistor 111, and an inverter 112. The gate of the PMOS transistor 110 is coupled to the voltage-generation circuit 10 at a node N10, the source thereof is coupled to an operation voltage VDD, and the source thereof is coupled to the node N12. The gate of the NMOS transistor 11 is coupled to the voltage-generation circuit 10 at a node N11, the drain thereof is coupled to the node N12, and the source thereof is coupled to the operation voltage VSS. In the embodiment, the operation voltage VDD is, for example, 1.8V, and the operation voltage VSS is lower than the operation voltage VDD, such as being equal to 0V or lower than 0V. The inverter 112 is coupled to the node N12 and generates the output signal OUT of the delay circuit 1.

The voltage-generation circuit 10 receives the input signal IN of the delay circuit 1. The voltage-generation circuit 10 generates control voltages V10 and V11 and provides the control voltages V10 and V22 to the nodes N10 and N11 respectively. When the level of the input signal IN switches to the high level from the low level, the control voltage V10 generated by the voltage-generation circuit 10 turns off the PMOS transistor 110. At the same time, when the level of the input signal IN switches to the high level from the low level, the voltage-generation circuit 10 also generates the control voltage V11 to the node N11. In the embodiment, the control voltage V11 which is generated by the voltage-generation circuit 10 in this case has a high level, however the control voltage V11 cannot turn on the NMOS transistor 111 completely. Thus, a voltage level of a delay control signal S10 at the node N12 cannot drop to the level of the operation voltage VSS from the level of the operation voltage VDD immediately. In this case, the voltage level of the delay control signal S10 drops to the level of the operation voltage VSS from the level of the operation voltage VDD gradually by a falling slope. In the embodiment, the falling slope is determined by the control voltage V11. In detail, the falling slope is determined by the control voltage V11 which is generated by the voltage-generation circuit 10 when the level of the input signal IN switches to the high level from the low level. The inverter 112 is coupled to the node N12 to receive the delay control signal S12. As described above, the level of the delay control signal S12 drops gradually. Thus, when the level of the delay control signal S12 drops to a threshold level, the inverter 112 switches the output signal OUT to be the high level.

When the level of the input signal IN switches to the low level from the high level, the control voltage V11 generated by the voltage-generation circuit 10 turns off the NMOS transistor 111. At the same time, when the level of the input signal IN switches to the low level from the high level, the voltage-generation circuit 10 also generates the control voltage V10 to the node N10. In the embodiment, the control voltage V10 which is generated by the voltage-generation circuit 10 in this case has a low level, however the control voltage V10 cannot turn on the PMOS transistor 110 completely. Thus, the voltage level of the delay control signal S10 at the node N12 cannot rise to the level of the operation voltage VDD from the level of the operation voltage VSS immediately. In this case, the voltage level of the delay control signal S10 rises to the level of the operation voltage VDD from the level of the operation voltage VSS gradually by a rising slope. In the embodiment, the rising slope is determined by the control voltage V10. In detail, the rising slope is determined by the control voltage V10 which is generated by the voltage-generation circuit 10 when the level of the input signal IN switches to the low level from the high level. The inverter 112 is coupled to the node N12 to receive the delay control signal S12. As described above, the level of the delay control signal S12 rises gradually. Thus, when the level of the delay control signal S12 rises to a threshold level, the inverter 112 switches the output signal OUT to be the low level.

According to the above embodiment, the delay control signal S12 gradually drops/rises with the level switching of the input signal IN, so that the rising edge of the output signal OUT is delayed from the rising edge of the input signal IN, and the falling edge of the output signal OUT is delayed from the falling edge of the input signal IN. Moreover, the falling slope of the delay control signal S12 is determined by the control voltage V11, and the rising slope thereof is determined by the control signal V10. Thus, the rising delay time by which the rising edge of the output signal OUT is delayed from the rising edge of the input signal IN is determined by the control voltage V11, while the falling delay time by which the falling edge of the output signal OUT is delayed from the falling edge of the input signal IN is determined by the control voltage V10. Compared with conventional delay circuits, the delay circuit 1 of the embodiment achieves the target delay time without increasing the number of capacitive and resistive elements or the number of inverters. According to the operation of the delay circuit 1, the falling slope and the rising slope of the delay control signal S12 are changed only by adjusting the control voltages V10 and V11, thereby changing the rising delay time and the falling delay time between the output signal OUT and input signal IN. In an embodiment, the rising delay time is equal to the falling delay time.

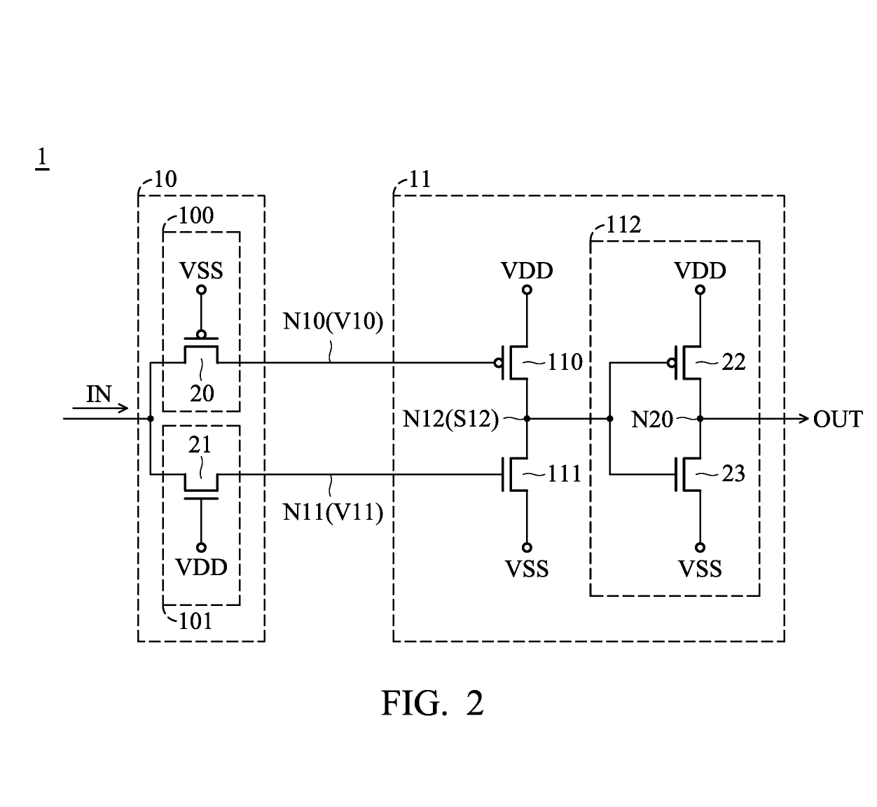

FIG. 2 shows another exemplary embodiment of a delay circuit. In FIGS. 1 and 2, the same elements are represented by the same reference signs. The embodiment of FIG. 2 shows exemplary structures of the voltage-generation circuit 10 and the inverter 12. Referring to FIG. 2, the voltage-generation circuit 10 comprises a boost element 100 and a buck element 101. The buck element 101 receives the operation voltage VDD. When the level of the input signal IN switches to the high level from the low level, the buck element 101 generates the control voltage V11, which is lower than the operation voltage VDD, to the node N11 for turning on the NMOS transistor 111. The boost element 100 receives the operation voltage VSS. When the level of the input signal IN switches to the low level from the high level, the boost element 100 generates the control voltage V10, which is higher than the operation voltage VSS, to the node N10 for turning on the PMOS transistor 110.

In an embodiment, the boost element 100 comprises a PMOS transistor 20, while the buck element 101 comprises an NMOS transistor 21. The gate of the PMOS transistor 20 is coupled to the operation voltage VSS, the source thereof receives the input signal IN, and the drain thereof receives the node N10. The gate of the NMOS transistor 21 is coupled to the operation voltage VDD, the drain thereof receives the input signal IN, and the source thereof receives the node N11. Based on the structure of the boost element 100 and the buck element 101, the PMOS transistor 20 and the NMOS transistor 21 are continuously turned on when the delay circuit 1 is powered on. In other words, the PMOS transistor 20 and the NMOS transistor 21 are turned on simultaneously.

Referring to FIG. 2, the inverter 112 comprises a PMOS transistor 22 and an NMOS transistor 23. The gate of the PMOS transistor 22 is coupled to the node N12, the source thereof is coupled to the operation voltage VDD, and the drain thereof is coupled to a node N20. The gate of the NMOS transistor 23 is coupled to the node N12, the drain thereof is coupled to the node N20, and the source thereof is coupled to the operation voltage VSS.

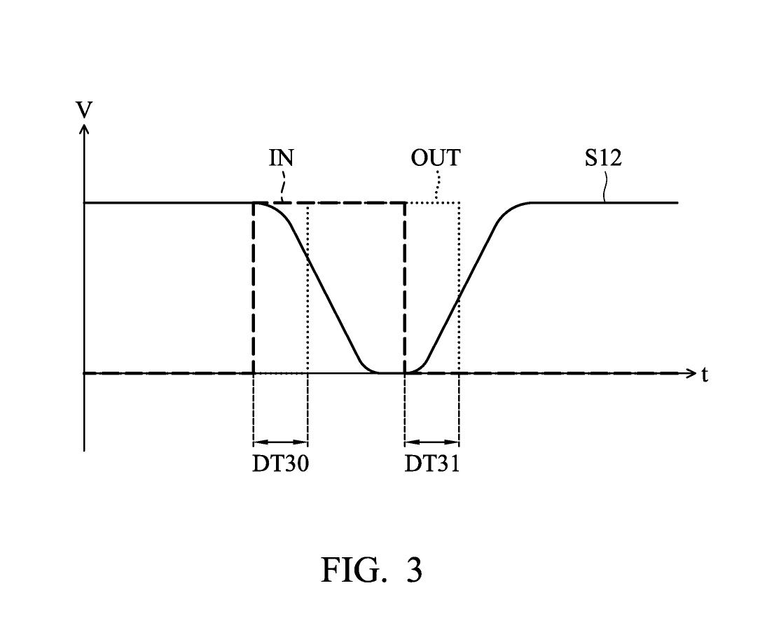

Referring to FIGS. 2 and 3, when the level of the input signal IN switches to the level of the operation voltage VDD from the level of the operation voltage VSS, the control voltage V10 is equal to the operation voltage VDD, so that the PMOS transistor 110 is turned off. At the same time, when the level of the input signal IN switches to the level of the operation voltage VDD from the level of the operation voltage VSS, the control voltage V11 is equal to the result of subtracting the threshold voltage V_{TH} of the NMOS transistor 21 from the operation voltage VDD (V11=VDD−V_{TH}). Since the level at the gate of the NMOS transistor 111 (that is, the control voltage V11) is lower than the operation voltage VDD, the NMOS transistor 111 is not turned on completely. Accordingly, the level of the delay control signal S12 at the node N12 cannot drop to the level of the operation voltage VSS from the level of the operation voltage VDD immediately, but drops to the level of the operation voltage VSS from the level of the operation voltage VDD gradually by a falling slope. According to the embodiment, the falling slope is determined by the control voltage V11 which is generated by the voltage-generation circuit 10 when the level of the input signal IN switches to the level of the operation voltage VDD from the level of the operation voltage VSS. When the level of the delay control signal S12 drops to a threshold level, the PMOS transistor 22 is turned on, so that the level of the output voltage OUT at the node N20 switches to the level of the operation voltage VDD from the level of the operation voltage VSS.

Referring to FIGS. 2 and 3 again, when the level of the input signal IN switches to the level of the operation voltage VSS from the level of the operation voltage VDD, the control voltage V11 is equal to the operation voltage VSS, so that the NMOS transistor 111 is turned off. At the same time, when the level of the input signal IN switches to the level of the operation voltage VSS from the level of the operation voltage VDD, the control voltage V10 is equal to the sum of the operation VSS and the threshold voltage V_{TH} of the PMOS transistor 20 (V10=VSS+V_{TH}). Since the level at the gate of the PMOS transistor 110 (that is, the control voltage V10) is higher than the operation voltage VSS, the PMOS transistor 110 is not turned on completely. Accordingly, the level of the delay control signal S12 at the node N12 cannot rise to the level of the operation voltage VDDS from the level of the operation voltage VSS immediately, but rises to the level of the operation voltage VDD from the level of the operation voltage VSS gradually by a rising slope. According to the embodiment, the rising slope is determined by the control voltage V10 which is generated by the voltage-generation circuit 10 when the level of the input signal IN switches to the level of the operation voltage VSS from the level of the operation voltage VDD. When the level of the delay control signal S12 rises to a threshold level, the NMOS transistor 23 is turned on, so that the level of the output voltage OUT at the node N20 switches to the level of the operation voltage VSS from the level of the operation voltage VDD.

According to the above embodiments, the delay control signal S12 gradually drops/rises with the level switching of the input signal IN, so that the rising edge of the output signal OUT is delayed from the rising edge of the input signal IN, and the falling edge of the output signal OUT is delayed from the falling edge of the input signal IN. Moreover, the falling slope of the delay control signal S12 is determined by the control voltage V11, and the rising slope thereof is determined by the control signal V10. Thus, the rising delay time DT30 (shown in FIG. 3) by which the rising edge of the output signal OUT is delayed from the rising edge of the input signal IN is determined by the control voltage V11, while the falling delay time DT31 (shown in FIG. 3) by which the falling edge of the output signal OUT is delayed from the falling edge of the input signal IN is determined by the control voltage V10. Compared with conventional delay circuits, the delay circuit 1 of the embodiment achieves the target delay time without an increase in the number of capacitive and resistive elements or the number of inverters. According to the operation of the delay circuit 1, the falling slope and the rising slope of the delay control signal S12 are changed only by adjusting the control voltages V10 and V11, thereby changing the rising delay time and the falling delay time between the output signal OUT and input signal IN. In an embodiment, the rising delay time DT30 is equal to the falling delay time DT31.

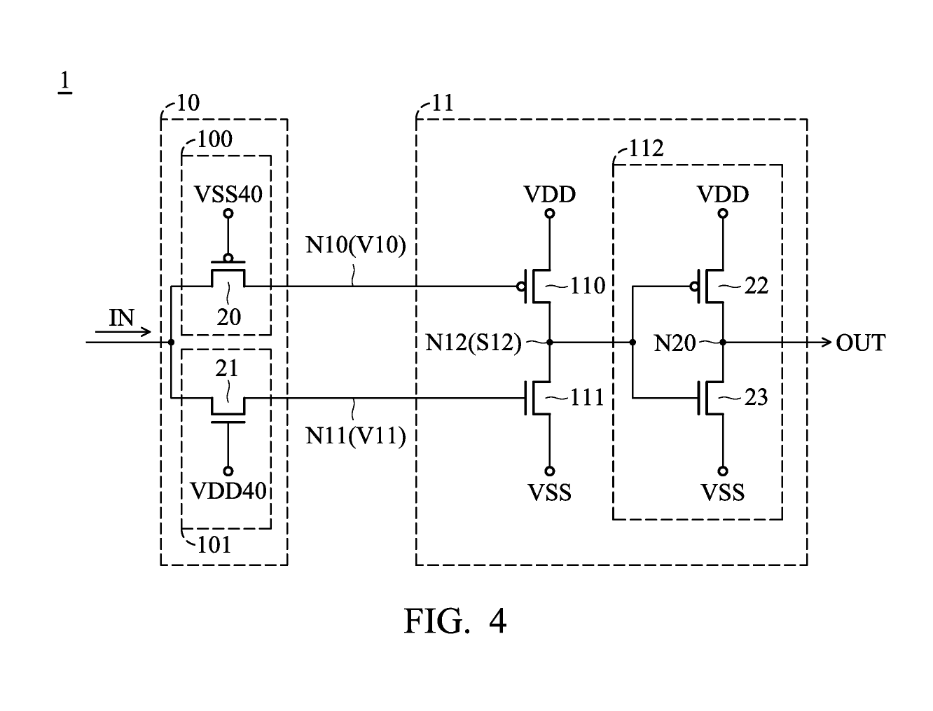

In an embodiment, the operation voltage coupled to the boost element 100 is different from the operation voltage VSS, and/or and the operation voltage coupled to the buck element 101 is different from the operation voltage VDD. Referring to FIG. 4, the gate of the PMOS transistor 20 of the boost element 100 is coupled to the operation voltage VSS40, and the gate of the NMOS transistor 21 of the buck element 101 is coupled to the operation voltage VDD40. In the embodiment, the operation voltage VSS40 is higher than or equal to the operation voltage VSS, and the operation voltage VDD40 is lower than or equal to the operation voltage VDD. The operation of the delay unit shown in FIG. 4 is similar to the above operation related to the embodiment of FIG. 2, and the related description is omitted here.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A delay circuit comprising:
a voltage-generation circuit receiving an input signal and generating a first control voltage and a second control voltage, wherein the voltage-generation circuit receives a first high operation voltage and a first low operation voltage which is lower than the first high operation voltage; and
a signal-generation circuit controlled by the first control voltage and the second control voltage to generate an output signal, wherein the signal-generation circuit receives a second high operation voltage and a second low operation voltage which is lower than the second high operation voltage,
wherein the first high operation voltage is lower than the second high operation voltage, and the first low operation voltage is higher than the second low operation voltage,
wherein a first delay time by which a falling edge of the output signal is delayed from a falling edge of the input signal is determined by the second control voltage, and a second delay time by which a rising edge of the output signal is delayed from a rising edge of the input signal is determined by the first control voltage.

2. The delay circuit as claimed in claim 1, wherein the voltage-generation circuit comprises:
a boost element receiving the first low operation voltage and generates the first control voltage, which is higher than the first low operation voltage, at a first node when the input signal is on a first level; and
a buck element receiving the first high operation voltage and generating the second control voltage, which is lower than the first high operation voltage, at a second node when the input signal is on a second level,
wherein the first level is lower than the second level.

3. The delay circuit as claimed in claim 2,
wherein the boost element comprises a P type-transistor having a gate receiving the first low operation voltage, a source receiving the input signal, and a drain coupled to the first node, and
wherein the buck element comprises an N-type transistor having a gate receiving the first high operation voltage, a drain receiving the input signal, and a source coupled to the second node.

4. The delay circuit as claimed in claim 3, wherein the P-type transistor and the N-type transistor are turned on simultaneously.

5. The delay circuit as claimed in claim 3, wherein when the delay circuit is powered on, the P-type transistor and the N-type transistor are continuously turned on.

6. The delay circuit as claimed in claim 1, wherein the signal-generation circuit comprises:
a P-type transistor having a gate receiving the first control voltage, a source coupled to the second high operation voltage, and a drain coupled to a first node; and
an N-type transistor having a gate receiving the second control voltage, a drain coupled to the first node, and a source coupled to the second low operation voltage;
wherein a delay control signal is generated at the first node.

7. The delay circuit as claimed in claim 6,
wherein a rising slope by which the delay control signal rises from a level of the second low operation voltage is determined by the first control voltage, and
wherein a falling slope by which the delay control signal drops from a level of the second high operation voltage is determined by the second control voltage.

8. The delay circuit as claimed in claim 6, wherein the signal-generation circuit comprises an inverter which receives the delay control signal and generates the output signal according to the delay control signal.

9. The delay circuit as claimed in claim 1,
wherein the first control voltage is higher than the first low operation voltage, and the second control voltage is lower than the first high operation voltage.

10. The delay circuit as claimed in claim 1, wherein the first delay time is equal to the second delay time.

11. A delay circuit comprising:
a first P-type transistor having a gate receiving a first low operation voltage, a source receiving an input signal, and a drain coupled to a first node;
a first N-type transistor having a gate receiving a first high operation voltage, a drain receiving the input signal, and a source coupled to a second node;
a second P-type transistor having a gate coupled to the first node, a source coupled to a second high operation voltage, and a drain coupled to a third node, wherein the first high operation voltage is lower than the second high operation voltage;
a second N-type transistor having a gate coupled to the second node, a drain coupled to the third node, and a source coupled to a second low operation voltage, wherein the first low operation voltage is higher than the second low operation voltage; and
an inverter, coupled to the third node, generating an output signal delayed from the input signal,
wherein the first P-type transistor and the first N-type transistor are turned on simultaneously.

12. The delay circuit as claimed in claim 11, wherein when the delay circuit is powered on, the P-type transistor and the N-type transistor are continuously turned on.

13. The delay circuit as claimed in claim 11, wherein a first delay time by which a falling edge of the output signal is delayed from a falling edge of the input signal is determined by a voltage at the second node, and a second delay time by which a rising edge of the output signal is delayed from a rising edge of the input signal is determined by a voltage at the first node.

14. The delay circuit as claimed in claim 13, wherein the first delay time is equal to the second delay time.

15-16. (canceled)

17. The delay circuit as claimed in claim 11, wherein the inverter comprises:
a third P-type transistor having a gate coupled to the third node, a source coupled to the second high operation voltage, and a drain coupled to a fourth node; and
a third N-type transistor having a gate coupled to the third node, a drain coupled to the fourth node, and a source coupled to the second low operation voltage.
